(19) United States
(12) Patent Application Publication
(10) Pub. No.: US 2025/0048727 A1
(43) Pub. Date: Feb. 6, 2025

(54) SEMICONDUCTOR DEVICE

(71) Applicant: Samsung Electronics Co., Ltd., Suwon-si (KR)

(72) Inventors: CHANGHUN KIM, Suwon-si (KR); JAEICK SON, Suwon-si (KR)

(21) Appl. No.: 18/611,960

(22) Filed: Mar. 21, 2024

(30) Foreign Application Priority Data
Jul. 31, 2023 (KR) 10-2023-0099456

(51) Int. Cl. H01L 27/092; H01L 29/06; H01L 29/423; H01L 29/66

(52) U.S. Cl. CPC H01L 27/0921; H01L 27/0922; H01L 29/0615; H01L 29/0696; H01L 29/42364; H01L 29/6656

(57) ABSTRACT

A semiconductor device includes a first substrate doped with an impurity of a first conductivity-type, a first well region formed in the first substrate and doped with an impurity of a second conductivity-type, different from the first conductivity-type, a first guard band that extends in a first direction, parallel to an upper surface of the substrate, is in the first well region, and doped with an impurity of the second conductivity-type, a second guard band facing the first guard band, in the substrate, and doped with an impurity of the first conductivity-type, a first electrode structure electrically connected to the first guard band, a second electrode structure electrically connected to the second guard band, and a first insulating layer on sidewalls of the first electrode structure and the second electrode structure, the first electrode structure, the insulating layer, and the second electrode structure provide a capacitor.

### CROSS-REFERENCE TO RELATED APPLICATION(S)

This application claims the benefit under 35 USC 119 (a) of Korean Patent Application No. 10-2023-0099456 filed on Jul. 31, 2023 in the Korean Intellectual Property Office, the entire disclosure of which is incorporated herein by reference for all purposes.

### BACKGROUND

The present inventive concept relates to a semiconductor device.

A Complementary Metal Oxide Semiconductor (CMOS) transistor is a device in which a PMOS transistor and an NMOS transistor are insulated from each other and disposed on the same chip so that both operate complementarily. In general, a CMOS transistor includes a PNPN-structured Silicon Controlled Rectifier (SCR) comprised of a parasitic PNP transistor and a parasitic NPN transistor.

Latch up refers to an unintended current flowing due to a parasitic bipolar transistor, impairing the characteristics of CMOS, when the vertical PNP transistor (or NPN transistor), a parasitic bipolar component of the PNPN structured CMOS transistor, and the horizontal structured NPN transistor (or PNP transistor) operate simultaneously and enter a low impedance state.

A guard band is disposed around the MOS transistor to prevent latch-up, preventing parasitic transistors from operating by absorbing minority carriers and preventing potential differences from occurring.

### SUMMARY

Example embodiments provide a semiconductor device in which power stability may be improved while preventing parasitic elements from operating by providing a guard band.

According to example embodiments, a semiconductor device includes a substrate doped with an impurity of a first conductivity-type, a first well region in the substrate and doped with an impurity of a second conductivity-type, different from the first conductivity-type, a first guard band that extends in a first direction, that is parallel to an upper surface of the substrate, is in the first well region, and is doped with an impurity of the second conductivity-type, a second guard band facing the first guard band in the substrate and doped with an impurity of the first conductivity-type, a plurality of first main wirings stacked on the first guard band in a third direction that is perpendicular to the upper surface of the substrate, ones of the plurality of first main wirings are electrically connected to each other by a plurality of first vias, and electrically connected to the first guard band through one or more first contacts, a plurality of second main wirings stacked on the second guard band in the third direction, ones of the plurality of second main wirings are electrically connected to each other by a plurality of second vias, and electrically connected to the second guard band through one or more second contacts, a plurality of first finger wires that extend from the plurality of first main wirings, respectively, in a second direction, parallel to the upper surface of the substrate and intersecting the first direction, a plurality of second finger wires that extend from the plurality of second main wirings, respectively, in a fourth direction that is parallel to the upper surface of the substrate and opposite to the second direction, and an insulating layer on sidewalls of the plurality of first main wirings, on sidewalls of the plurality of second main wirings, on sidewalls of the plurality of first finger wires, and on sidewalls of the plurality of second finger wires. The plurality of first finger wires and the plurality of second finger wires alternate at least in the first direction.

According to example embodiments, a semiconductor device includes a substrate doped with an impurity of a first conductivity-type, a first well region in the substrate and doped with an impurity of a second conductivity-type, different from the first conductivity-type, a first guard band that extends in a first direction, that is parallel to an upper surface of the substrate, is in the first well region, and is doped with an impurity of the second conductivity-type, a second guard band facing the first guard band, within the substrate, and doped with an impurity of the first conductivity-type, a plurality of first main wirings stacked on the first guard band in a third direction, perpendicular to the substrate, electrically connected to each other by a plurality of first vias, and electrically connected to the first guard band through one or more first contacts, a plurality of second main wirings stacked on the second guard band in the third direction, electrically connected to each other by a plurality of second vias, and electrically connected to the second guard band through one or more second contacts, and an insulating layer on sidewalls of the plurality of first main wirings and on sidewalls of the plurality of second main wirings. An electrode structure is not between the plurality of first main wirings and the plurality of second main wirings.

According to example embodiments, a semiconductor device includes a substrate doped with an impurity of a first conductivity-type, a first well region formed in the substrate and doped with an impurity of a second conductivity-type, different from the first conductivity-type, a first guard band that extends in a first direction, that is parallel to an upper surface of the substrate, is in the first well region, and is doped with an impurity of the second conductivity-type, a second guard band facing the first guard band, in the substrate, and doped with an impurity of the first conductivity-type, a first electrode structure electrically connected to the first guard band, a second electrode structure electrically connected to the second guard band, and an insulating layer on sidewalls of the first electrode structure and on sidewalls of the second electrode structure. The first electrode structure, the insulating layer, and the second electrode structure provide a capacitor.

### BRIEF DESCRIPTION OF DRAWINGS

The above and other aspects, features, and advantages of the present inventive concept will be more clearly understood from the following detailed description, taken in conjunction with the accompanying drawings, in which:

FIG. 1 is a diagram illustrating a semiconductor device according to example embodiments;

FIG. 2 is a cross-sectional view taken along line I-I′ of FIG. 1;

FIG. 3 is a diagram illustrating a semiconductor device according to example embodiments;

FIG. 4 is a cross-sectional view taken along line II-II′ of FIG. 3;

FIG. 5 is a cross-sectional view taken along line III-III′ of FIG. 3;

FIG. 6 is a diagram illustrating a semiconductor device according to example embodiments;

FIG. 7 is a cross-sectional view taken along line IV-IV′ of FIG. 6;

FIG. 8 is a cross-sectional view taken along line V-V′ of FIG. 6;

FIG. 9 is a diagram illustrating a semiconductor device according to example embodiments;

FIG. 10 is a cross-sectional view taken along line VI-VI′ of FIG. 9;

FIG. 11 is a cross-sectional view taken along line VII-VII of FIG. 9;

FIG. 12 is a diagram illustrating a semiconductor device according to example embodiments;

FIG. 13 is a diagram illustrating a semiconductor device according to example embodiments;

FIG. 14 is a diagram illustrating a semiconductor device according to example embodiments;

FIG. 15 is a diagram illustrating a semiconductor device according to example embodiments; and

FIG. 16 is a diagram illustrating a semiconductor layout design method according to example embodiments.

### DETAILED DESCRIPTION

Hereinafter, example embodiments will be described with reference to the accompanying drawings.

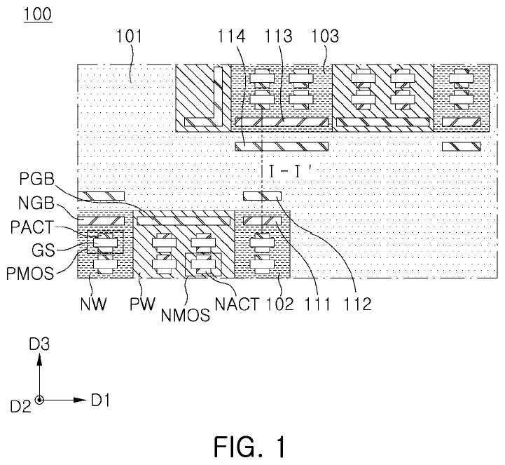

FIG. 1 is a diagram for explaining a semiconductor device according to example embodiments.

Referring to FIG. 1, a semiconductor device 100 may include a substrate 101 and first type well regions (PW) and second type well regions (NW) formed in the substrate 101. For example, the substrate 101 and the first type well regions (PW) may be doped with an impurity of a first conductivity-type, and the second type well regions (NW) may be doped with an impurity of a second conductivity-type. The first conductivity-type may be P-type, and the second conductivity-type may be N-type. Hereinafter, first conductivity-type or type 1 well regions are referred to as P well regions (PW), and second conductivity-type or type 2 well regions are referred to as N well regions (NW).

PMOS transistors (PMOS) may be formed in the N-well regions (NW), and NMOS transistors (NMOS) may be formed in the P-well regions (PW). The PMOS transistors (PMOS) may include first active regions (PACT) and a gate structure (GS) doped with P-type impurities, and the NMOS transistors NMOS may include second active regions NACT and a gate structure GS doped with N-type impurities. A power supply voltage may be applied to the first active area (PACT) of the PMOS transistor (PMOS), and a ground voltage may be applied to the second active area (NACT) of the NMOS transistor (NMOS).

CMOS transistors may include PMOS transistors (PMOS) and NMOS transistors (NMOS). A CMOS transistor may have a PNPN structure consisting of a first active area (PACT), an N-well area (NW), a P-well area (PW), and a second active area (NACT). If an unwanted forward bias is formed in the PNPN structure due to a cause such as noise being applied to the CMOS transistor, the CMOS transistor operates like a Silicon Controlled Rectifier (SCR), which may cause overcurrent.

To prevent latch-up that may occur in the CMOS transistor, the semiconductor device 100 may include a guard band. For example, the N-well region (NW) may include an N-type guard band (NGB) around the PMOS transistors (PMOS) doped with impurities of a second conductivity-type at a higher concentration than the N-well region (NW), and the P well region (PW) may include a P-type guard band (PGB) around the NMOS transistors (NMOS) doped with impurities of the first conductivity-type at a higher concentration than the P well region (PW).

By applying the power supply voltage to the N-type guard band (NGB), the N-well region (NW) may be biased with the power supply voltage, and as a ground voltage is applied to the P-type guard band (PGB), the P well region (PW) may be biased to the ground voltage. Electrons flowing into the N-well region (NW) may escape externally through the N-type guard band (NGB), and holes flowing into the P-well region (PW) may escape externally through the P-type guard band (PGB), thereby preventing latch-up of CMOS transistors.

On the other hand, a power short may occur between N-well regions (NW) that are spaced apart from each other and are each biased with a power supply voltage. For example, between the first well region 102 and the second well region 103 among the N well regions (NW), the first well region 102, the substrate 101, and the second well region 103 are formed. A power short may occur due to the operation of the configured parasitic elements.

According to example embodiments, a P-type guard band may be formed on the substrate 101 of the semiconductor device 100 opposite to the N-type guard band (NGB) included within the N-well region (NW). For example, a second guard band 112 opposing the first guard band 111, which is an N-type guard band (NGB) included within the second well region 103, may be further formed on the substrate 101. In the example of FIG. 1, when the first guard band 111 extends in the first direction D1 parallel to the upper surface of the substrate 101, the second guard band 112 may also extend in the first direction D1. the second guard band 112 may be doped with an impurity of the first conductivity-type the same as a conductivity type of the substrate 101, and a ground voltage may be applied to the second guard band 112.

According to example embodiments, the substrate 101 is biased to the ground voltage by the second guard band 112, thereby preventing operation of the parasitic element consisting of the first well region 102, the substrate 101, and the second well region 103. As a result, the occurrence of power short may be prevented.

In addition, the semiconductor device 100 may further include a first electrode structure for connecting the first guard band 111 to the power supply voltage and a second electrode structure for connecting the second guard band 112 to the ground voltage. The first electrode structure and the second electrode structure may be arranged to face each other. Accordingly, the first electrode structure and the second electrode structure may provide a power capacitor. As a result, the stability of the power supply voltage and ground voltage may be improved.

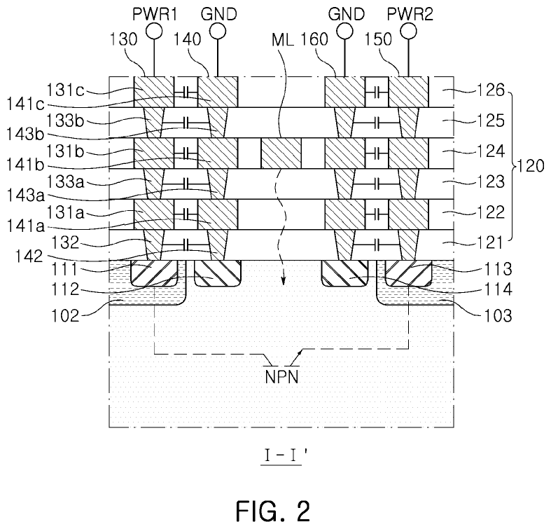

Below, the structure of the guard band and power capacitor of the semiconductor device 100 according to example embodiments is described in more detail with reference to FIG. 2.

FIG. 2 is a view taken along line I-I′ of FIG. 1.

Referring to FIG. 2, the first well region 102, the substrate 101, and the second well region 103 may have a parasitic NPN transistor (NPN). For example, the first well region 102, the substrate 101, and the second well region 103 may respectively provide a collector, base, and emitter of a parasitic NPN transistor.

The first well region 102 includes a first guard band 111 doped with an impurity of a second conductivity-type, and the second well region 103 may include a third guard band 113 doped with an impurity of a second conductivity-type. The electrode structure 130 formed on the upper surface of the first guard band 111 is electrically connected to the first power pad (PWR1), and the first well region 102 may be biased with the first power source. Also, the electrode structure 150 formed on the upper surface of the third guard band 113 is electrically connected to the second power pad PWR2, so that the second well region 103 may be biased with the second power source. The first power source and the second power source may have the same potential or different potentials. On the other hand, the electrode structures 130 and 150 may be formed in the insulating layer 120.

On the other hand, a metal wire ML may be disposed on the upper part of the substrate 101. The parasitic NPN transistor (NPN) may be turned on due to the voltage applied to the metal wiring (ML). In detail, when the semiconductor device 100 is a device that uses high voltage of several tens of volts, such as a flash memory device, the potential of the substrate 101 may increase due to the high voltage applied to the metal wiring ML, thereby turning on the parasitic NPN transistor.

When the parasitic NPN transistor (NPN) is turned on, a power short may occur in which a low-impedance current path is formed between the first power pad (PWR1) and the second power pad (PWR2). When a power short circuit occurs, a large amount of current flows between the first power pad (PWR1) and the second power pad (PWR2), and sufficient current may not flow through devices such as PMOS transistors. Therefore, a power short may cause malfunction of semiconductor devices.

According to example embodiments, the substrate 101 may include P-type guard bands 112 and 114 around each of the N-type guard bands 111 and 113. As described with reference to FIG. 1, the first guard band 111 and the second guard band 112 may extend in directions parallel to each other, and the third guard band 113 and the fourth guard band 114 may extend in directions parallel to each other.

An electrode structure 140 may be formed on the upper surface of the second guard band 112, and an electrode structure 160 may be formed on the upper surface of the fourth guard band 114. The substrate 101 may be biased with a ground voltage by connecting the ground pad (GND) to each of the electrode structure 140 and the electrode structure 160.

According to example embodiments, the substrate 101 may be biased with a ground voltage. Accordingly, even if a voltage is applied to the metal wiring ML, the voltage of the substrate 101 is fixed to the ground voltage, thereby preventing the operation of the parasitic NPN transistor. Accordingly, a power short circuit between the first power source (PWR1) and the second power source (PWR2) may be prevented, and malfunction of the semiconductor device 100 may be prevented.

On the other hand, the first electrode structure 130 formed on the upper surface of the first guard band 111 and the second electrode structure 140 formed on the upper surface of the second guard band 112 may face each other with the insulating layer 120 interposed therebetween. The first electrode structure 130 to which the first power is applied, the insulating layer 120, and the second electrode structure 140 to which the ground power is applied may provide a power capacitor. The insulating layer 120 between the first electrode structure 130 and the second electrode structure 140 may function as a dielectric layer.

Similarly, the third electrode structure 150 to which the second power is applied, the insulating layer 120, and the fourth electrode structure 140 to which the ground power is applied may also provide a power capacitor.

Depending on the example embodiment, no electrode structure may be intervening between the first electrode structure 130 and the second electrode structure 140, and there may also be no electrode structure intervening between the third electrode structure 150 and the fourth electrode structure 160.

Additionally, the opposing electrode structures may be spaced apart by a distance close enough to provide a power capacitor required by the semiconductor device 100. For example, the separation distance between the first electrode structure 130 and the second electrode structure 140 and the separation distance between the third electrode structure 150 and the fourth electrode structure 160 may be the same as the minimum distance defined in the layout design rules. However, the separation distance between electrode structures may be greater than the minimum distance.

Depending on the example embodiment, the first electrode structure 130, the insulating layer 120, and the second electrode structure 140 may form a vertical capacitor. The insulating layer 120 may include a plurality of insulating layers 121-126. The first electrode structure 130 may be formed in the plurality of insulating layers 121-126, and may include first wirings 131a, 131b and 131c, a first contact 132, and first vias 133a and 133b, stacked in the third direction D3 perpendicular to the upper surface of the substrate 101 from the upper surface of the first guard band 111. The first contact 132 may be connected to the first wiring 131a of the lowest layer among the first wirings 131a, 131b, and 131c and the first guard band 111, and each of the first vias 133a and 133b may electrically connect the first wirings 131a, 131b, and 131c by connecting to adjacent first electrodes.

Similarly, the second electrode structure 140 may be formed in a plurality of insulating layers 121-126 and may include a plurality of second wirings 141a, 141b, and 141c, a second contact 142, and second vias 143a and 143b, stacked in the third direction D3 from the upper surface of the second guard band 122. The second contact 142 may be connected to the second wiring 141a of the lowest layer among the second wirings 141a, 141b, and 141c and the second guard band 112, and each of the second vias 143a and 143b may electrically connect the second wirings 141a, 141b, and 141c by connecting to adjacent second electrodes.

Depending on example embodiments, the electrode structures 130, 140, 150, and 160 may extend to the upper surface of the insulating layer 120. For example, the upper surfaces of the electrode structures 130, 140, 150, and 160 may be exposed to the upper surface of the insulating layer 120 and may be connected to a power pad or a ground pad. However, the present inventive concept is not limited to the structure of the electrode structures 130, 140, 150, and 160 necessarily extending to the upper surface of the insulating layer 120.

According to example embodiments, the electrode structures 140 and 160 formed to apply a ground voltage (GND) to the P-type guard bands 112 and 114 formed on the substrate 101 may respectively form a power capacitor, along with the electrode structures 130 and 150. For example, the semiconductor device 100 does not include additional structures for providing a power capacitor, and by using a power capacitor as a structure for biasing the substrate 101 to the ground voltage, noise in the first power voltage (PWR1), the second power voltage (PWR2), and the ground voltage (GND) may be effectively removed. As a result, the stability of the power supply voltages PWR1 and PWR2 and the ground voltage (GND) may be improved while efficiently using the circuit area of the semiconductor device 100.

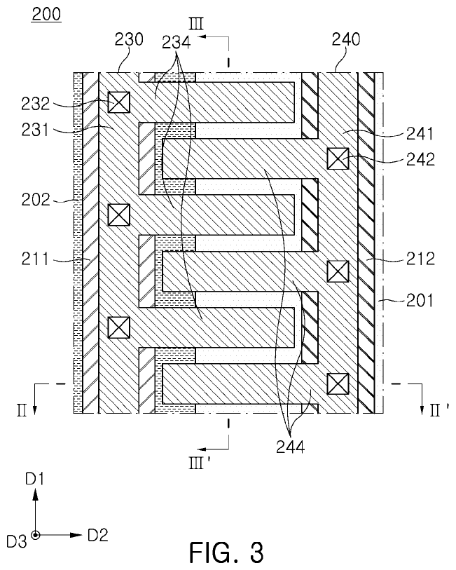

According to example embodiments, electrode structures disposed on the upper surfaces of the first guard band and the second guard band may have various shapes to provide a power capacitor. Below, semiconductor devices according to various example embodiments are described in detail with reference to FIGS. 3 to 14.

FIG. 3 is a diagram illustrating a semiconductor device according to example embodiments.

Referring to FIG. 3, a semiconductor device 200 may include a substrate 201 doped with an impurity of a first conductivity-type, and a first well region 202 formed in the substrate 201 and doped with an impurity of a second conductivity-type.

Like the semiconductor device 100 described with reference to FIGS. 1 and 2, the semiconductor device 200 of FIG. 3 may include a first guard band 211 formed in the first well region 202, doped with an impurity of a second conductivity-type, and extending in the first direction D1, and a second guard band 212 formed in the substrate 201, doped with an impurity of a first conductivity-type, and extending in the first direction D1.

In addition, the semiconductor device 200 may include a first electrode structure 230 connected to the first guard band 211 on the upper surface of the first guard band 211, and a second electrode structure 240 connected to the second guard band 212 on the upper surface of the second guard band 212.

When the power voltage is applied to the first electrode structure 230, the first well region 202 is biased with the power voltage, and by applying a ground voltage to the second electrode structure 240, the substrate 201 may be biased to the ground voltage.

According to example embodiments, the first electrode structure 230 may include at least one first main wiring 231 and a plurality of first finger wires 234 extending from the first main wiring 231 in the second direction D2. The first main wiring 231 may be electrically connected to the first guard band 211 through the first contact 232. The second direction D2 may be parallel to the upper surface of the substrate 201 and intersect the first direction D1.

In addition, the second electrode structure 240 may include at least one second main wiring 241 and a plurality of second finger wires 244 extending from the second main wiring 241 in a direction opposite to the second direction D2. The second main wiring 241 may be electrically connected to the second guard band 212 through the second contact 242.

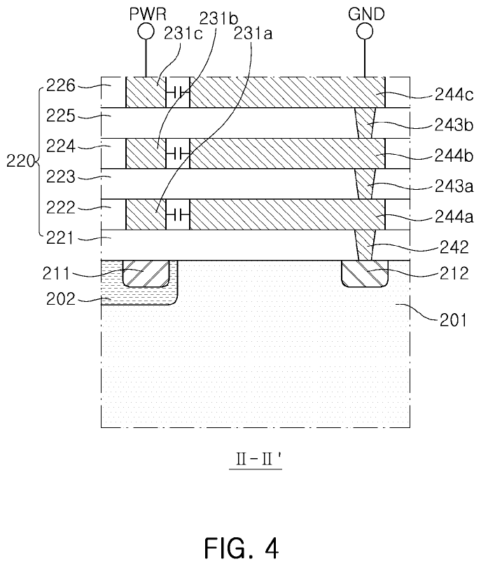

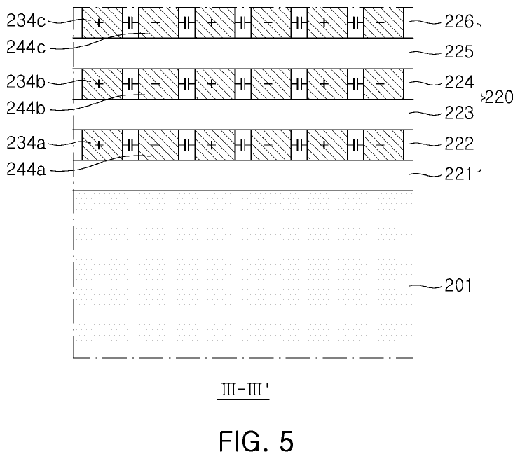

According to example embodiments, a plurality of first finger wires 234 and a plurality of second finger wires 244 may be alternately disposed in the first direction D1. Below, the structure of the semiconductor device 200 of FIG. 3 is described in more detail with reference to FIGS. 4 and 5.

FIG. 4 is a cross-sectional view taken along line II-II′ of FIG. 3.

Referring to FIG. 4, an insulating layer 220 may be disposed on the upper surface of the substrate 201, and the first and second electrode structures 230 and 240 described with reference to FIG. 3 may be disposed in the insulating layer 220.

One or more first main wirings 231 may include a plurality of first main wirings 231a, 231b, and 231c. In addition, one or more second main wirings 241 may include a plurality of second main wirings 241a, 241b, and 241c.

The plurality of first finger wires 234 may extend from each of the plurality of first main wirings 231a, 231b, and 231c, and the plurality of second finger wires 244 may extend from each of the plurality of second main wirings 241a, 241b, and 241c. FIG. 4 illustrates second finger wires 244a, 244b, and 244c extending from a plurality of second main wirings 241a, 241b, and 241c.

The second main wiring 241a may be connected to the second guard band 212 through the second contact 242, and the plurality of second main wirings 241a, 241b, and 241c may be electrically connected to each other by second vias 243a and 243b. Although not illustrated in FIG. 4, the first main wiring 231a may be connected to the first guard band 211 through the first contact 232, and the plurality of first main wirings 231a, 231b, and 231c may be electrically connected to each other by first vias.

FIG. 5 is a cross-sectional view taken along line III-III′ of FIG. 3.

Referring to FIG. 5, a plurality of first finger wires 234a and a plurality of second finger wires 244a formed in the second insulating layer 222, a plurality of first finger wires 234b and a plurality of second finger wires 244b formed in the fourth insulating layer 224, and a plurality of first finger wires 234c and a plurality of second finger wires 244c formed in the sixth insulating layer 226, are illustrated.

The first and second finger wires formed in the same insulating layer may be alternately disposed in the first direction D1 to provide capacitance. On the other hand, the first finger wires 234a, 234b, and 234c formed in different insulating layers may be aligned in the third direction D3, and the second finger wires 244a, 244b, and 244c formed in different insulating layers may be aligned in the third direction D3.

According to example embodiments, the plurality of finger wires 234a and 244a, the plurality of finger wires 234b and 244b, and the plurality of finger wires 234c and 244c may be disposed alternately in the first direction D1. Accordingly, the area of the power capacitor provided by the first electrode structure 230, the insulating layer 220, and the second electrode structure 240 increases, and the electrostatic capacity may be improved.

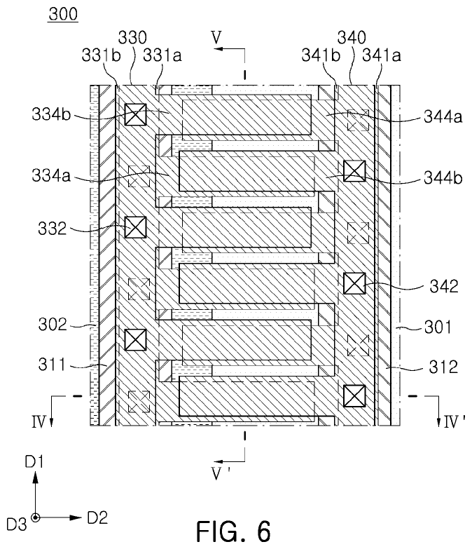

FIG. 6 is a diagram illustrating a semiconductor device according to example embodiments.

Referring to FIG. 6, a semiconductor device 300 may include a substrate 301 doped with an impurity of a first conductivity-type, and a first well region 302 formed in the substrate 301 and doped with an impurity of a second conductivity-type.

Like the semiconductor device 100 described with reference to FIGS. 1 and 2, the semiconductor device 300 of FIG. 6 may include a first guard band 311 formed in the first well region 302, doped with an impurity of a second conductivity-type, and extending in the first direction D1, and a second guard band 312 is formed in the substrate 301, is doped with an impurity of a first conductivity-type, and extends in the first direction D1.

The semiconductor device 300 may include a first electrode structure 330 connected to the first guard band 311 on the upper surface of the first guard band 311, and a second electrode structure 340 connected to the second guard band 312 on the upper surface of the second guard band 312. A power voltage may be applied to the first electrode structure 330, and a ground voltage may be applied to the second electrode structure 340.

The first electrode structure 330 may include a plurality of first main wirings 331a and 331b, and the second electrode structure 340 may include a plurality of second main wirings 341a and 341b. On the other hand, the plurality of respective first main wirings 331a and 331b and the plurality of respective second main wirings 341a and 341b may be disposed in the same position on the plane of FIG. 6, but are slightly misaligned in FIG. 6.

The first electrode structure 330 may include a plurality of first finger wires 334a and 334b extending from each of the first main wirings 331a and 331b in the second direction D2. The second electrode structure 340 may include a plurality of second finger wires 344a and 344b extending from each of the second main wirings 341a and 341b in a direction opposite to the second direction D2.

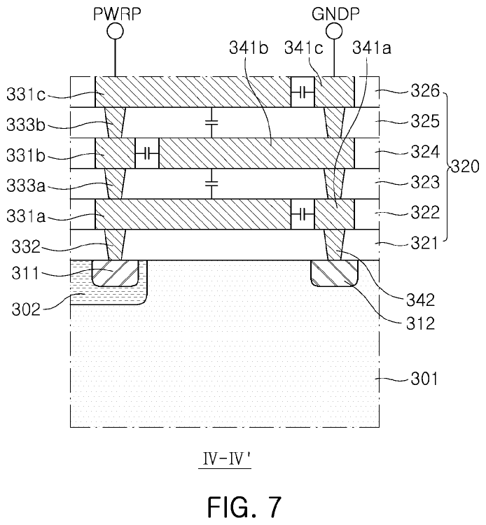

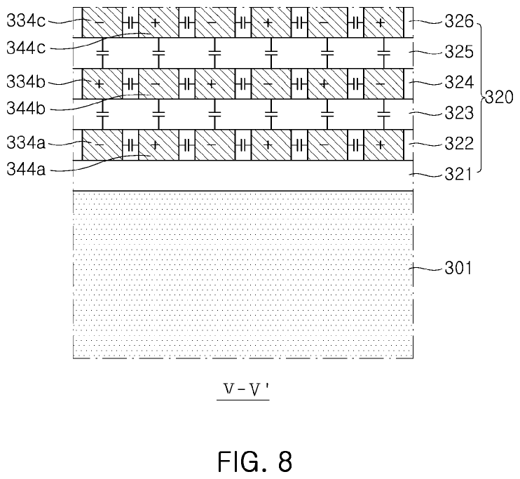

According to example embodiments, a plurality of first finger wires 334a and 334b and a plurality of second finger wires 344a and 344b may be alternately disposed in the first direction D1 and the third direction D3. Below, the structure of the semiconductor device 300 of FIG. 6 is described in more detail with reference to FIGS. 7 and 8.

FIG. 7 is a cross-sectional view taken along line IV-IV′ of FIG. 6.

Referring to FIG. 7, an insulating layer 320 may be disposed on the upper surface of the substrate 301, and the first and second electrode structures 330 and 340 may be disposed in the insulating layer 320.

The first electrode structure 330 may include a plurality of first main wirings 331a, 331b, and 331c, a first contact 332, and a plurality of first vias 333a and 333b. The second electrode structure 340 may include a plurality of second main wirings 341a, 341b, and 341c, a second contact 342, and a plurality of second vias 343a and 343b.

In the example of FIG. 7, the first finger wire 334a extending from the first main wiring 331a, the second finger wire 344b extending from the second main wiring 341b, and a first finger wire 334c extending from the first main wiring 331c are illustrated.

According to example embodiments, the first finger wire 334a, the second finger wire 344b, and the first finger wire 334c overlap in the third direction D3, thereby providing a power capacitor.

FIG. 8 is a cross-sectional view taken along line V-V′ of FIG. 6.

Referring to FIG. 8, a plurality of first finger wires 334a and a plurality of second finger wires 344a formed in the second insulating layer 322, a plurality of first finger wires 334b and a plurality of second finger wires 344b formed in the fourth insulating layer 324, and a plurality of first finger wires 334c and a plurality of second finger wires 344c formed in the sixth insulating layer 326 are illustrated.

According to example embodiments, first and second finger wires formed in the same insulating layer may be alternately disposed in the first direction D1 to provide capacitance. Additionally, the first and second finger wires formed in different insulating layers may be alternately disposed in the third direction D3 to provide capacitance.

A plurality of first finger wires 334a, 334b, 334c and a plurality of second finger wires 344a, 344b, 344c are alternately disposed in the first direction D1 and the third direction D3. The area of the power capacitor provided by the first electrode structure 330, the insulating layer 320, and the second electrode structure 340 may increase, and the electrostatic capacity may increase.

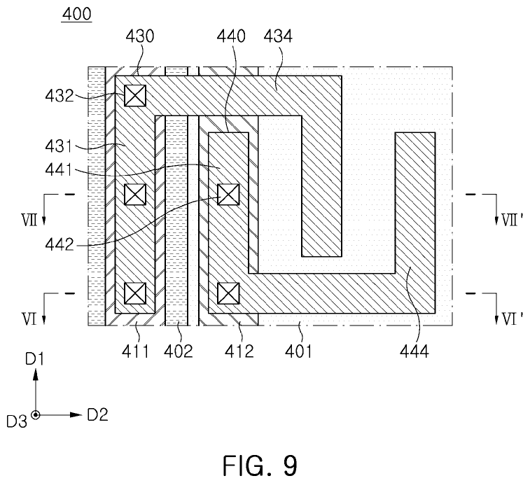

FIG. 9 is a diagram illustrating a semiconductor device according to example embodiments.

Referring to FIG. 9, a semiconductor device 400 may include a substrate 401 doped with an impurity of a first conductivity-type, and a first well region 402 formed in the substrate 401 and doped with an impurity of a second conductivity-type.

Like the semiconductor device 100 described with reference to FIGS. 1 and 2, the semiconductor device 400 in FIG. 9 may include a first guard band 411 formed in the first well region 402, doped with an impurity of a second conductivity-type, and extending in a first direction D1 parallel to the upper surface of the substrate, and a second guard band 412 is formed in the substrate 401, is doped with an impurity of a first conductivity-type, and extends in the first direction D1.

The semiconductor device 400 may include a first electrode structure 430 connected to the first guard band 411 on the upper surface of the first guard band 411, and a second electrode structure 440 connected to the second guard band 412 on the upper surface of the second guard band 412. A power voltage may be applied to the first electrode structure 430, and a ground voltage may be applied to the second electrode structure 440.

According to example embodiments, the first electrode structure 430 may include at least one first main wiring 431, a first contact 432 connected to the first main wiring 431 and the first guard band 411, and a first sub-wiring 434 connected to the end of the first main wiring 431 in the first direction (D1). The first sub-wiring 434 may be connected to the first main wiring 431 in the second direction D2 from the first well region 402 toward the substrate 401.

In addition, the second electrode structure 440 may include at least one second main wiring 441, a second contact 442 connected to the second main wiring 441 and the second guard band 412, and a second sub-wiring 444 connected to an end of the second main wiring 441 in a direction opposite to the first direction D1. The second sub-wiring 444 may be connected to the second main wiring 441 in the second direction D2.

Depending on the example embodiment, the first sub-wiring 434 and the second sub-wiring 444 may each have an L-shape, and the first electrode structure 430 and the second electrode structure 440 may each have a U-shape.

Depending on the example embodiment, an electrode structure may not be intervening between the first main wiring 431 and the second main wiring 441.

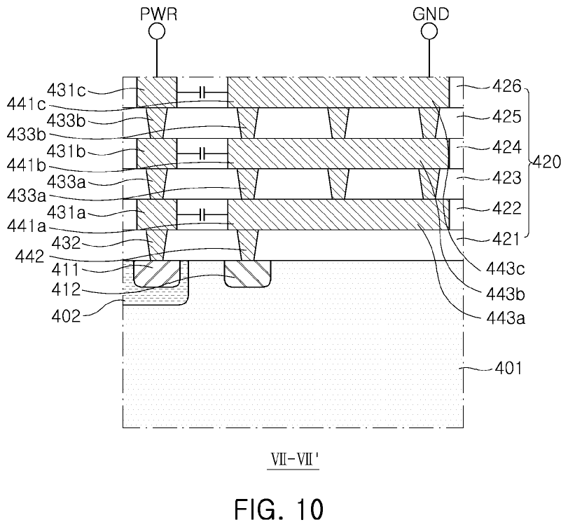

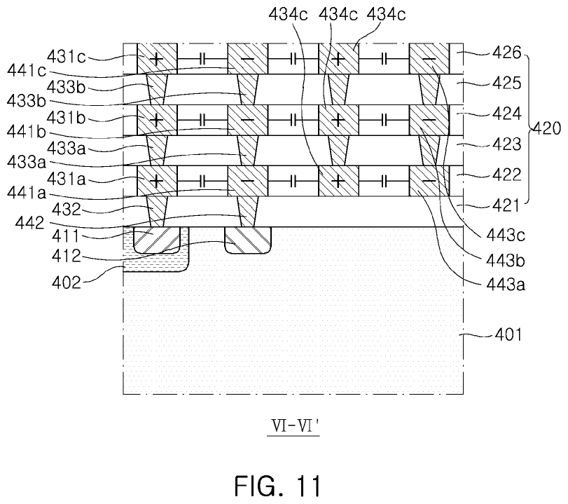

According to example embodiments, a power capacitor may be provided by arranging the first electrode structure 430 and the second electrode structure 440 in a structure that engages each other in the plane of FIG. 9. For example, the first electrode structure 430 and the second electrode structure 440 may have portions alternately disposed in the second direction D2. Below, the structure of the semiconductor device 400 of FIG. 9 is described in more detail with reference to FIGS. 10 and 11.

FIG. 10 is a cross-sectional view taken along line VI-VI′ of FIG. 9. FIG. 11 is a cross-sectional view taken along line VII-VII of FIG. 9.

Referring to FIGS. 10 and 11 together, an insulating layer 420 may be disposed on the upper surface of the substrate 401, and the first and second electrode structures 430 and 440 described with reference to FIG. 9 may be disposed in the insulating layer 420.

The first electrode structure 430 may include a plurality of first main wirings 431a, 431b, 431c, a first contact 432, a plurality of first vias 433a, 433b, and a plurality of first sub-wirings 434a, 434b and 434c. The second electrode structure 440 may include a plurality of second main wirings 441a, 441b and 441c, a second contact 442, a plurality of second vias 443a and 443b, and a plurality of second sub-wirings 444a, 444b and 444c.

A power voltage may be applied to the first electrode structure 430 and a ground voltage may be applied to the second electrode structure 440. Accordingly, the first electrode structure 430 and the second electrode structure 440 may function as a power capacitor.

Referring to FIG. 11, the first main wiring, second main wiring, first sub-wiring, and second sub-wiring formed in the same insulating layer are alternately disposed to increase the area of the power capacitor.

With reference to FIGS. 9 to 11, a case in which the first electrode structure 430 and the second electrode structure 440 are interlocked and arranged so that the sub-wirings have an L-shape has been described. However, wires extending from the main wirings may have various shapes.

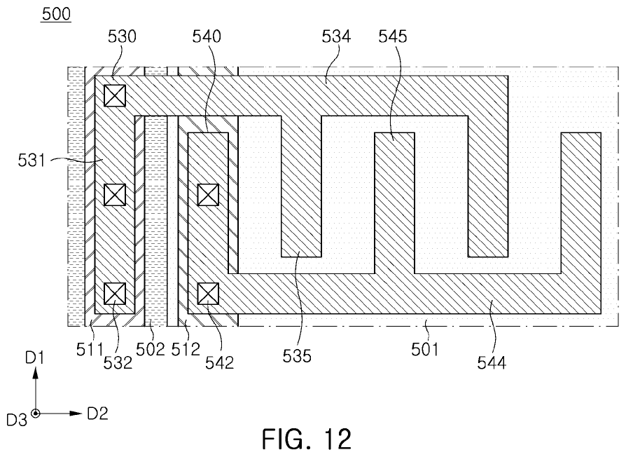

FIG. 12 is a diagram illustrating a semiconductor device according to example embodiments.

Referring to FIG. 12, a semiconductor device 500 may include a substrate 501 doped with an impurity of a first conductivity-type, and a first well region 502 formed in the substrate 501 and doped with an impurity of a second conductivity-type.

The semiconductor device 500 in FIG. 12 may include a substrate 501, a first well region 502, a first guard band 511, and a second guard band 512, in a structure similar to the structure of the semiconductor device 400 described with reference to FIGS. 9 to 11. Below, the semiconductor device 500 of FIG. 12 will be described in detail, focusing on differences from the semiconductor device 400.

The semiconductor device 500 may include a first electrode structure 530 connected to the first guard band 511 on the upper surface of the first guard band 511, and a second electrode structure 540 connected to the second guard band 512 on the upper surface of the second guard band 512. A power voltage may be applied to the first electrode structure 530, and a ground voltage may be applied to the second electrode structure 540.

According to example embodiments, the first electrode structure 530 may include at least one first main wiring 531 extending in a first direction D1 parallel to the upper surface of the substrate 501, at least one first sub-wiring 534 extending from the first main wiring 531 in a second direction (D2) crossing the first direction (D1), and a plurality of first finger wires 535 extending from the first sub-wiring 534 and parallel to the first main wiring 531.

In addition, the second electrode structure 540 may include at least one second main wiring 541 extending in the first direction D1, at least one second sub-wiring 544 extending from the second main wiring 541 in the second direction D2, and a plurality of second finger wires 545 extending from the second sub-wiring 544 and parallel to the second main wiring 535.

FIG. 12 illustrates one first main wiring 531, one first sub-wiring 534, a plurality of first finger wires 535 extending from one first sub-wiring 534, one second main wiring 541, one second sub-wiring 544, and a plurality of second finger wires 545 from one second sub-wiring 544, as an example. However, similar to the case of the semiconductor device 400 described with reference to FIGS. 9 to 11, wires may be stacked in a plurality of insulating layers.

According to example embodiments, the first sub-wiring 533, the second sub-wiring 543, the plurality of first finger wires 535, and the plurality of second finger wires 545 are alternately disposed in the second direction D2, thereby providing a power capacitor.

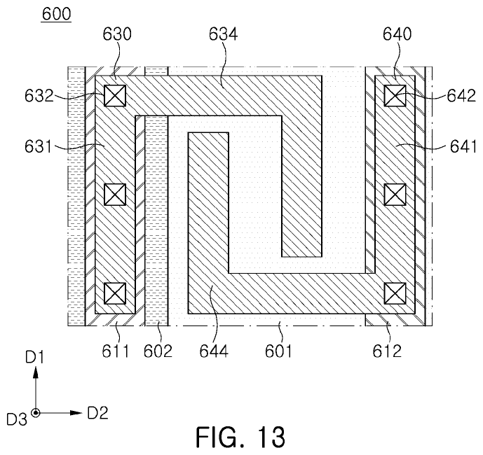

FIG. 13 is a diagram illustrating a semiconductor device according to example embodiments.

A semiconductor device 600 in FIG. 13 may include a substrate 601, a first well region 602, a first guard band 611, and a second guard band 612, in a structure similar to the semiconductor device 400 described with reference to FIGS. 9 to 11. Below, the semiconductor device 600 of FIG. 13 will be described in detail, focusing on differences from the semiconductor device 400 described with reference to FIGS. 9 to 11.

The semiconductor device 600 may include a first electrode structure 630 connected to the first guard band 611 on the upper surface of the first guard band 611, and a second electrode structure 640 connected to the second guard band 612 on the upper surface of the second guard band 612. A power voltage may be applied to the first electrode structure 630, and a ground voltage may be applied to the second electrode structure 640.

According to example embodiments, the first electrode structure 630 may include at least one main wiring 631, a first contact 632 connected to the first main wiring 631 and the first guard band 611, and a first sub-wiring 634 connected to the end of the first main wiring 631 in the first direction (D1). The first sub-wiring 634 having an L-shape may be connected to the first main wiring 631 in the second direction D2 from the first well region 602 toward the substrate 601.

The second electrode structure 640 may include at least one second main wiring 641, a second contact 642 connected to the second main wiring 641 and the second guard band 612, and a second main wiring 641, and a second sub-wiring 644 connected to an end of the second main wiring 641 in a direction opposite to the first direction D1. The second sub-wiring 644 having an L-shape may be connected to the second main wiring 641 in a direction opposite to the second direction D2.

According to example embodiments, a power capacitor may be provided by arranging the first electrode structure 630 and the second electrode structure 640 in a structure that engages each other in the plane of FIG. 13.

On the other hand, of course, the present inventive concept may be applied even when the first well region doped with an impurity of the second conductivity-type is a deep-well region containing one or more well regions.

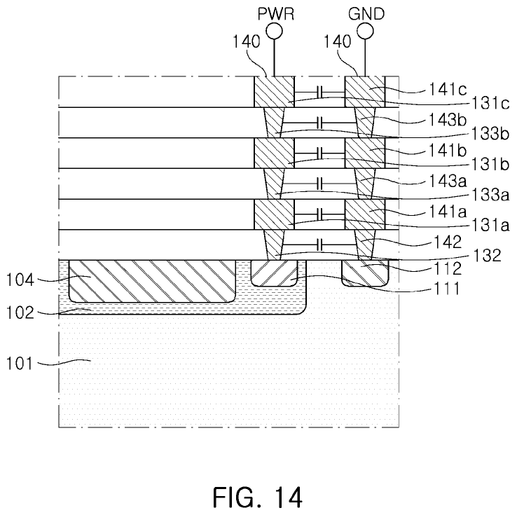

FIG. 14 is a diagram illustrating a semiconductor device according to example embodiments.

FIG. 14 provides the substrate 101, the first well region 102, the first guard band 111, the second guard band 112, the insulating layer 120, the first electrode structure 130, and the second electrode structure 140.

According to example embodiments, the first well region 102 may be a deep-well region including the third well region 104. Even in the case in which the first well region 102 is a deep-well region, a second guard band 112 may be formed around the first guard band 111 included in the first well region 102, in the substrate 101. Additionally, the first electrode structure 130 connected to the first guard band 111 and the second electrode structure 140 connected to the second guard band 112 may provide a power capacitor. On the other hand, the third well region 104 in the deep-well region may not be biased.

On the other hand, a semiconductor device may be formed in a structure in which a plurality of chips are stacked. According to example embodiments, a plurality of electrode structures for providing a power capacitor may be formed across two or more chips.

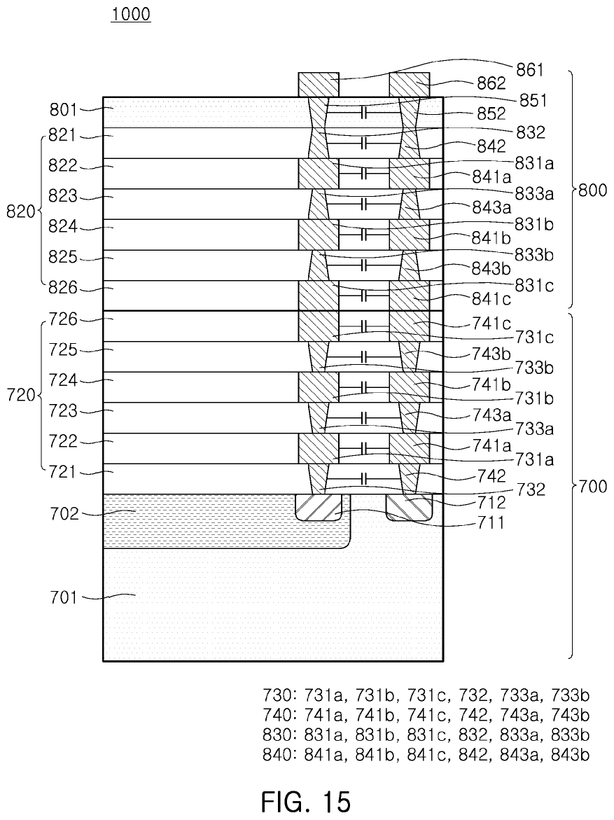

FIG. 15 illustrates a semiconductor device 1000 according to example embodiments.

Referring to FIG. 15, the semiconductor device 1000 may include a first chip 700 and a second chip 800. The first chip 700 may include a first substrate 701 on which semiconductor devices are formed and a first insulating layer 720 on which metal wires are formed. Like the first chip 700, the second chip 800 may include a second substrate 801 and a second insulating layer 820. The semiconductor device 1000 may be formed by bonding the second chip 800 to the upper surface of the first chip 700 in an upside-down state. The first chip 700 may be referred to as a lower chip, and the second chip 800 may be referred to as an upper chip.

According to example embodiments, a first well region 702 is disposed on the substrate 701, a first guard band 711 is disposed in the first well region 702, and a second guard band 712 may be disposed in the first substrate 701. Also, the first electrode structure 730 and the second electrode structure 740 may be disposed in the first insulating layer 720.

The first electrode structure 730 may include a plurality of first main wirings 731a, 731b, and 731c, one or more first contacts 732, and a plurality of first vias 733a, 733b. Additionally, the second electrode structure 740 may include a plurality of second main wirings 741a, 741b, and 741c, one or more second contacts 742, and a plurality of second vias 743a, 743b.

The first electrode structure 730 may be connected to the upper surface of the first guard band 711 and may have a shape extending in a third direction D3 perpendicular to the upper surface of the first substrate 701, and may be exposed through the upper surface of the first insulating layer 720. Similarly, the second electrode structure 740 may be connected to the upper surface of the second guard band 712, may extend in the third direction D3, and may be exposed through the upper surface of the first insulating layer 720.

According to example embodiments, the third electrode structure 830 and the fourth electrode structure 840 may be disposed in the second insulating layer 820. The third electrode structure 830 may include third main wirings 831a, 831b, and 831c, one or more third contacts 832, and a plurality of third vias 833a and 833b. Additionally, the fourth electrode structure 840 may include fourth main wirings 841a, 841b, and 841c, one or more fourth contacts 842, and a plurality of fourth vias 843a, 843b.

The third main wiring 831c is exposed on the upper surface of the insulating layer 820, and the third contact 832 may be connected to the first contact plug 851 included in the second substrate 801. In addition, the fourth main wiring 841c is exposed on the upper surface of the insulating layer 820, and the fourth contact 842 may be connected to the second contact plug 852 included in the second substrate 801.

According to example embodiments, the first chip 700 and the second chip 800 are bonded, such that the first main wiring 731c and the third main wiring 831c are electrically connected, and the second main wiring 731c and the fourth main wiring 741c may be electrically connected.

The second chip 800 may further include a power pad 861 and a ground pad 862. A power supply voltage may be applied to the first guard band 711 by the first electrode structure 730 and the third electrode structure 830. In addition, a ground voltage may be applied to the second guard band 712 by the second electrode structure 740 and the fourth electrode structure 840.

In addition, the first electrode structure 730 and the third electrode structure 830, and the second electrode structure 740 and the fourth electrode structure 840, may provide a power capacitor in the form in which they face each other.

According to example embodiments, when a plurality of chips are stacked in the semiconductor device 1000, the first well region 702 is biased with a power supply voltage by placing electrode structures that extend across a plurality of chips and face each other, and by biasing the substrate 701 with a ground voltage, a power capacitor with increased capacitance may be provided.

For example, in the present inventive concept, the memory cell area is implemented with a first chip, the peripheral circuit area is implemented with a second chip, and may be applied to flash memory devices such as COP (Cell on Peri) NAND and Bonding V-NAND (BVNAND) in which the first chip and the second chip are stacked vertically.

On the other hand, in the semiconductor layout design device, the layout design of the second guard band formed around the first guard band and the second electrode structure formed on top of the second guard band may be automated. For example, a processor executing instructions loaded in a memory may determine the arrangement and shape of the second guard band and the second electrode structure in the main layout of the semiconductor device by executing the specified instructions.

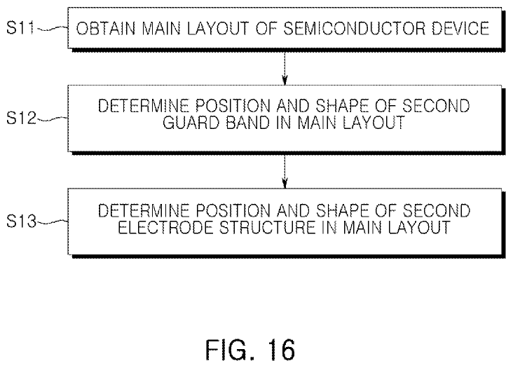

FIG. 16 is a diagram illustrating a semiconductor layout design method according to example embodiments.

In operation S11, the main layout of the semiconductor device may be obtained. The main layout of the semiconductor device may include N-well regions formed on a P-type substrate, P-well regions, semiconductor elements, wiring patterns, and a first guard band formed for well biasing of the N-well regions.

In operation S12, the arrangement and shape of the second guard band in the main layout may be determined. For example, the second guard band is in the P-type substrate, and the position and shape of the second guard band may be determined to have a shape extending in a direction parallel to the first guard band at a position having a predetermined distance from the first guard band.

In operation S13, the arrangement and shape of the second electrode structure in the main layout may be determined. For example, in the second electrode structure, the position and shape of the second electrode structure may be determined to have a shape that faces or engages the first electrode structure at a position opposite the first electrode structure within the second guard band.

As set forth above, a semiconductor device according to example embodiments includes a second guard band formed on a substrate doped with an impurity of a first conductivity-type, thereby preventing the parasitic NPN transistor of the first well region and the substrate doped with impurities of the second conductivity-type and the second well region doped with impurities of the second conductivity-type from operating. Accordingly, the leakage current of the semiconductor device may be reduced and the reliability of the semiconductor device may be improved.

In a semiconductor device according to example embodiments, the stability of the power supply may be improved by using the first electrode structure electrically connected to the first guard band formed in the first well region and the second electrode structure electrically connected to the second guard band as a power capacitor.

While example embodiments have been illustrated and described above, it will be apparent to those skilled in the art that modifications and variations could be made without departing from the scope of the present inventive concept as defined by the appended claims.

What is claimed is:

1. A semiconductor device comprising:
a substrate doped with an impurity of a first conductivity-type;
a first well region in the substrate and doped with an impurity of a second conductivity-type, different from the first conductivity-type;
a first guard band that extends in a first direction that is parallel to an upper surface of the substrate, is in the first well region, and is doped with an impurity of the second conductivity-type;
a second guard band facing the first guard band in the substrate and doped with an impurity of the first conductivity-type;
a plurality of first main wirings stacked on the first guard band in a third direction that is perpendicular to the upper surface of the substrate, wherein ones of the plurality of first main wirings are electrically connected to each other by a plurality of first vias, and electrically connected to the first guard band through one or more first contacts;
a plurality of second main wirings stacked on the second guard band in the third direction, wherein ones of the plurality of second main wirings are electrically connected to each other by a plurality of second vias, and electrically connected to the second guard band through one or more second contacts;
a plurality of first finger wires that extend from the plurality of first main wirings, respectively, in a second direction, parallel to the upper surface of the substrate and intersecting the first direction;
a plurality of second finger wires that extend from the plurality of second main wirings, respectively, in a fourth direction that is parallel to the upper surface of the substrate and opposite to the second direction; and
an insulating layer on sidewalls of the plurality of first main wirings, on sidewalls of the plurality of second main wirings, on sidewalls of the plurality of first finger wires, and on sidewalls of the plurality of second finger wires,
wherein the plurality of first finger wires and the plurality of second finger wires alternate at least in the first direction.

2. The semiconductor device of claim 1, wherein the plurality of first finger wires are aligned in the first direction and the third direction, and
wherein the plurality of second finger wires are aligned in the first direction and the third direction.

3. The semiconductor device of claim 1, wherein the plurality of first finger wires and the plurality of second finger wires alternate in the first direction and the third direction.

4. The semiconductor device of claim 1, wherein the plurality of first main wirings are electrically connected to a first power pad, and
wherein the plurality of second main wirings are electrically connected to a ground pad.

5. The semiconductor device of claim 1, further comprising:
a third well region in the first well region,
wherein the third well region is doped with an impurity of the second conductivity-type.

6. The semiconductor device of claim 1, wherein the first guard band is doped with a higher concentration of impurities than the first well region, and
wherein the second guard band is doped with a higher concentration of impurities than the substrate.

7. The semiconductor device of claim 1, wherein the first conductivity-type is P type, and the second conductivity-type is N type.

8. A semiconductor device comprising:
a substrate doped with an impurity of a first conductivity-type;
a first well region in the substrate and doped with an impurity of a second conductivity-type, different from the first conductivity-type;
a first guard band that extends in a first direction, that is parallel to an upper surface of the substrate, is in the first well region, and is doped with an impurity of the second conductivity-type;
a second guard band facing the first guard band, in the substrate, and doped with an impurity of the first conductivity-type;
a plurality of first main wirings stacked on the first guard band in a third direction that is perpendicular to the substrate, wherein ones of the plurality of first main wirings are electrically connected to each other by a plurality of first vias, and electrically connected to the first guard band through one or more first contacts;
a plurality of second main wirings stacked on the second guard band in the third direction, wherein ones of the plurality of second main wirings are electrically connected to each other by a plurality of second vias, and electrically connected to the second guard band through one or more second contacts; and
an insulating layer on sidewalls of the plurality of first main wirings and on sidewalls of the plurality of second main wirings,
wherein an electrode structure is not between the plurality of first main wirings and the plurality of second main wirings.

9. The semiconductor device of claim 8, wherein the semiconductor device comprises:
first sub-wirings extended to a second direction parallel to the upper surface and across the substrate and the first well region, and electrically connected to respective first ends of the plurality of respective first main wirings; and
second sub-wirings extended to the second direction and electrically connected to respective second ends of the plurality of second main wirings.

10. The semiconductor device of claim 9, wherein the first main wirings, the second main wirings, the first sub-wirings, and the second sub-wirings have portions alternately disposed in the second direction.

11. The semiconductor device of claim 9, wherein ones of the first sub-wirings and ones of the second sub-wirings respectively have an L-shape.

12. The semiconductor device of claim 8, further comprising:
a plurality of first sub-wirings that extend from the plurality of first main wirings, respectively, in a second direction, parallel to the upper surface of the substrate and intersecting the first direction;
a plurality of first finger wires that extend from the plurality of first sub-wirings in the first direction;
a plurality of second sub-wirings that extend from the plurality of second main wirings, respectively, in the second direction; and
a plurality of second finger wires that extend from the plurality of second sub-wirings in a direction opposite to the first direction,
wherein the plurality of first finger wires and the plurality of second finger wires alternate at least in the second direction.

13. The semiconductor device of claim 8, wherein a distance between the first guard band and the second guard band in a second direction that is parallel to the upper surface of the substrate and perpendicular to the first direction, is a minimum distance defined by a layout design rule.

14. A semiconductor device comprising:
a substrate doped with an impurity of a first conductivity-type;
a first well region formed in the substrate and doped with an impurity of a second conductivity-type, different from the first conductivity-type;
a first guard band that extends in a first direction that is parallel to an upper surface of the substrate, is in the first well region, and is doped with an impurity of the second conductivity-type;
a second guard band facing the first guard band, in the substrate, and doped with an impurity of the first conductivity-type;
a first electrode structure electrically connected to the first guard band;
a second electrode structure electrically connected to the second guard band; and
an insulating layer on sidewalls of the first electrode structure and on sidewalls of the second electrode structure,
wherein the first electrode structure, the insulating layer, and the second electrode structure comprise a capacitor.

15. The semiconductor device of claim 14, wherein the first well region is configured to be biased to a first power voltage by the first electrode structure, and
wherein the substrate is configured to be biased to a ground voltage by the second electrode structure.

16. The semiconductor device of claim 15, wherein the semiconductor device further comprises:
a second well region in the substrate, doped with an impurity of the second conductivity-type, and spaced apart from the first well region;
a third guard band doped with an impurity of the second conductivity-type, and in the second well region; and
a fourth guard band facing the third guard band, in the substrate, and doped with an impurity of the first conductivity-type,
wherein the second well region is configured to be biased by a second power voltage having a potential different from a potential of the first power voltage.

17. The semiconductor device of claim 15, wherein an upper surface of the first electrode structure and an upper surface of the second electrode structure are exposed to an upper surface of the insulating layer.

18. The semiconductor device of claim 15, wherein the substrate comprises a first substrate, wherein the insulating layer comprises a first insulating layer, and wherein the semiconductor device further comprises:
a lower chip including the first substrate, the first well region, the first guard band, the second guard band, the first electrode structure, the second electrode structure, and the first insulating layer; and
an upper chip including a second substrate and a second insulating layer, wherein an upper surface of the second insulating layer is bonded to an upper surface of the first insulating layer,
wherein the upper chip further includes a third electrode structure electrically connected to the first electrode structure and a fourth electrode structure electrically connected to the second electrode structure, in the second insulating layer.

19. The semiconductor device of claim 18, wherein the third electrode structure is electrically connected to a power pad, and the fourth electrode structure is electrically connected to a ground pad.

20. The semiconductor device of claim 15, wherein the first electrode structure includes a plurality of first main wirings stacked in a third direction, perpendicular to the substrate, and that extend in the first direction, and first sub-wirings electrically connected to respective ends of the plurality of first main wirings in a second direction toward the substrate from the first well region, and
wherein the second electrode structure includes a plurality of second main wirings stacked in the third direction and extending in the first direction, and second sub-wirings electrically connected on respective ends of the plurality of second main wirings in a direction opposite to the second direction,
wherein the first electrode structure and the second electrode structure have portions alternately disposed in the second direction.
